(19) United States
(12) Patent Application Publication
(10) Pub. No.: US 2012/0313728 A1
(43) Pub. Date: Dec. 13, 2012

(54) Apparatus for Capturing Electric Distribution System Harmonics for Powering Loads

(76) Inventor: John Louis Cairo, JR., Garnet Valley, PA (US)

(21) Appl. No.: 13/157,402

(22) Filed: Jun. 10, 2011

(51) Int. Cl. H03H 7/01

(52) U.S. Cl. 333/174; 333/175

(57) ABSTRACT

An apparatus for capturing power supply harmonics for use in powering a load, comprising a series resonant circuit coupled between an energy source having a waveform comprising a sinusoidal fundamental frequency and a sinusoidal harmonic, and a load that is not the earth, wherein the series resonant circuit is tuned to the harmonic frequency whereby the energy of the harmonic is directed to the load.

### BACKGROUND

In a conventional Alternating Current (AC) electric supply or distribution system, supplying electricity to a non-linear load results in harmonics arising on the supply line to the load. In the prior art, such harmonic energy is not used by the non-linear load, nor is it purposefully used by any other load coupled to the supply line. Instead, the harmonic energy is wasted as heat in the supply line and other elements of the electric distribution system. What is needed is a way to capture that wasted energy and use it to supply useful loads.

### SUMMARY

The herein described apparatus, systems, and methods are directed to a series tuned filter that captures harmonics on an electric distribution system for use in powering loads. The apparatus comprises at least one capacitor and at least one inductor connected in series and adapted to form a resonant circuit which, when coupled to a source of electrical energy having a waveform comprising a fundamental frequency and one or more harmonic frequencies and tuned to at least one of the harmonics, captures energy of that harmonic and directs the captured energy to supply a load.

Unless explicitly stated otherwise, both the foregoing general description and the following detailed description are exemplary and explanatory, and are intended to support and clarify the invention as claimed in the appended claims.

### BRIEF DESCRIPTION OF THE DRAWINGS

The accompanying drawings provide a further understanding of the claimed invention and are incorporated in and constitute a part of this specification, and serve to illustrate certain features of herein described exemplary embodiments of the claimed invention.

In the drawings:

FIGS. 1A and 1B are simplified electrical circuit schematic diagrams showing an AC supply mains that has a harmonic, and a harmonic capturing apparatus tuned to that harmonic and coupled to the supply mains to supply a load, in accordance with the herein disclosed systems and methods;

FIG. 2 is a simplified electrical circuit schematic diagram showing the apparatus of FIG. 1 with a sensor that senses when the harmonic is not available on the mains and, if not, switches the load to be supplied from the supply mains instead of from the harmonic capturing apparatus, in accordance with the herein disclosed systems and methods;

FIG. 3 is a simplified electrical circuit schematic diagram showing a harmonic capturing apparatus that is tunable to a select one of a plurality of harmonics;

FIG. 4 is a simplified electrical circuit schematic diagram showing a harmonic capturing apparatus comprising a plurality of branches, each branch tunable to a select harmonic;

FIG. 5 is a simplified electrical circuit schematic diagram showing a harmonic capturing apparatus arranged to increase the usable energy output of a DC generator coupled to an AC grid through an inverter; and

FIG. 6 is a simplified electrical circuit schematic diagram showing a harmonic capturing apparatus arranged to increase the usable energy supplied to a battery charger, whereby the time required to charge a battery may be reduced.

### DETAILED DESCRIPTION

It is to be understood that at least some of the figures and descriptions of exemplary implementations of the claimed invention may have been simplified to better illustrate elements that are relevant for a clear understanding of the invention, while eliminating, for purposes of clarity, other elements that are found in the prior art. Those of ordinary skill in the art will recognize that other elements may be desirable and/or required in order to implement the illustrative scenarios. Because such elements are well known in the art, and because they do not facilitate a better understanding of the claimed invention, a discussion of such elements may not be provided herein. Nevertheless, the specification and claims are intended to include all such elements, and all variations and modifications to the systems, methods, and apparatus disclosed herein, as would be known or apparent to those skilled in the art in light of this specification.

Spurious noise signals, including harmonic currents, background noise, and spike impulse noise often arise on power distribution lines. Such noise signals can originate from the power source, such as wind or solar power generators, from the distribution network, from non-linear loads coupled to the network, lightning strikes, distribution equipment malfunction, and the like. Consequently, the AC current supplied to an electric utility customer by the utility is generally not a pure sine wave and contains harmonics that may interfere with the proper operation of connected equipment.

Such noise may not be constant with respect to time, and also varies from place to place in the power distribution network. Moreover, a typical electrical distribution network distributes power to a variety of electrical load devices. Various devices may inject a significant level of noise and harmonic currents back onto the supply line, causing distortion of the power supply waveform. Different types of loads and control devices can produce different types and degrees of distortion that may interfere with the operation of equipment that is being powered by the distribution network. As Fourier analysis reveals, distortion to the periodic current and/or voltage waveforms provided by an electric power system can be shown to comprise harmonics of the fundamental frequency on the power line. The fundamental frequency is a consequence of the rotational speed of the rotors of electrical generators that provide power to the system. In the U.S. the fundamental power system frequency is 60 Hertz (Hz); in Europe and Asia, it is 50 Hz. Harmonics are multiples of the fundamental frequency of a wave, e.g., the 2nd harmonic being 120 Hz (in the U.S.), the 3rd harmonic 180 Hz, etc. As used herein, “harmonic” excludes the fundamental frequency.

The amount of electric power used by a device, and even the condition of the device itself, can be adversely affected by harmonics associated with waveform distortions present in its power supply. Typical problems associated with harmonics, such as harmonics resulting from nonlinear loads, can include overvoltages and current surges on the supply line, resulting in increased stress on conductor insulation and increased heating in transformers and conductors supplying the nonlinear load. This can result in a shortened nominal lifetime and/or a requirement for increased ampacity of equipment (i.e., overbuilding equipment to increase its ability to carry current). In addition, radio and telephone interference, interference with electronic controllers, and the like, can result from harmonics in an electric distribution system.

The prior art is essentially entirely directed to mitigating power line waveform distortion, commonly by directing the harmonics into the ground, without any attempt to harness the harmonic energy for useful purposes. However, the inventors have recognized that harmonic energy associated with such distortions can be captured and used to power loads, and doing so can still result in mitigating harmonics that would otherwise arise on the supply line. Benefits of the herein disclosed methods and systems can include providing substantial cost savings to energy consumers with respect to electrical energy consumption, which is achieved by capturing harmonic energy and using it to power loads. Benefits can further include cost savings associated with preventing premature failure of electrical equipment, reducing maintenance, and less frequent repair or replacement of electrical equipment.

As used herein, a linear electrical load is an electrical load or device with a linear relationship between the current through the load and the voltage across the load. On an AC system, such a load in steady state operation presents an essentially constant impedance to the electric power source throughout the cycle of an input AC sine wave. Non-limiting examples of linear loads include AC induction motors that apply torque to constant (time invariant) mechanical loads, and resistive lighting and heating elements. In contrast, a nonlinear load does not have a linear relationship between the current and voltage, for example, because it draws current discontinuously, or its impedance varies throughout the cycle of the input AC sine wave. Non-limiting examples of nonlinear loads include diodes, transistors, switch mode power supplies, computers, fluorescent lighting, voltage rectifiers, arc lighting, welding machines, variable frequency drive converter power supplies, switched mode power supplies, and induction motors that apply torque to time-varying mechanical loads.

Harmonic currents arising from a non-linear load flow away from the load into the power line supplying power to the load toward the distribution system. The injection of harmonic currents into the power distribution system can cause overheating of transformers, high neutral currents in grounded three phase, four wire systems, and the like. As harmonic currents flow through the distribution system, voltage drops result for each harmonic, causing distortion of the supply waveform throughout the system. The distorted waveform is applied to all loads connected to the same distribution system, adversely affecting their operation and efficiency.

For example, harmonic distortion of the voltage waveform on a supply line that arises due to a non-linear load on the line, is applied to an induction motor elsewhere on the line and can adversely affect motor performance by inducing harmonic fluxes in the motor magnetic circuit. The harmonic fluxes can cause heat build-up and additional losses in the motor magnetic core, which reduces power transfer efficiency. Inductive heating effects increase in proportion to the square of the harmonic current, and induction motors can be degraded, damaged, and even destroyed by such heating if the supply line waveform distortion is severe enough. The claimed invention can mitigate such waveform distortion while utilizing otherwise wasted energy in the waveform.

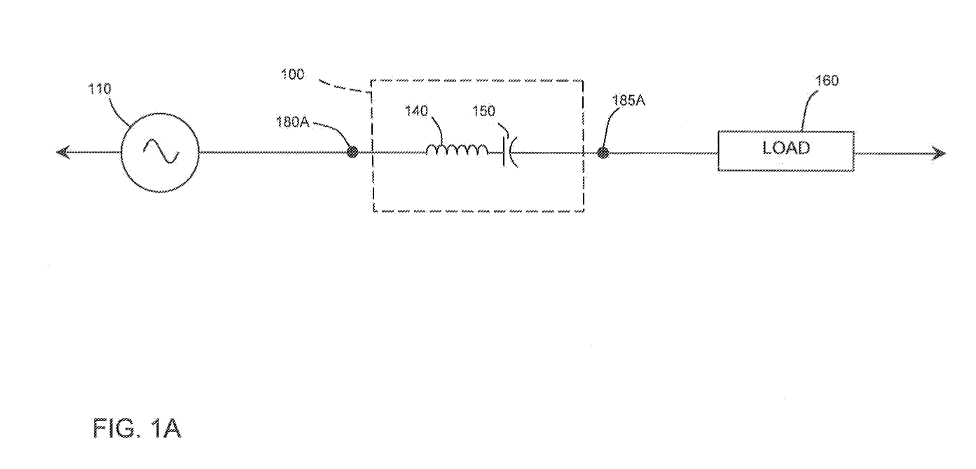

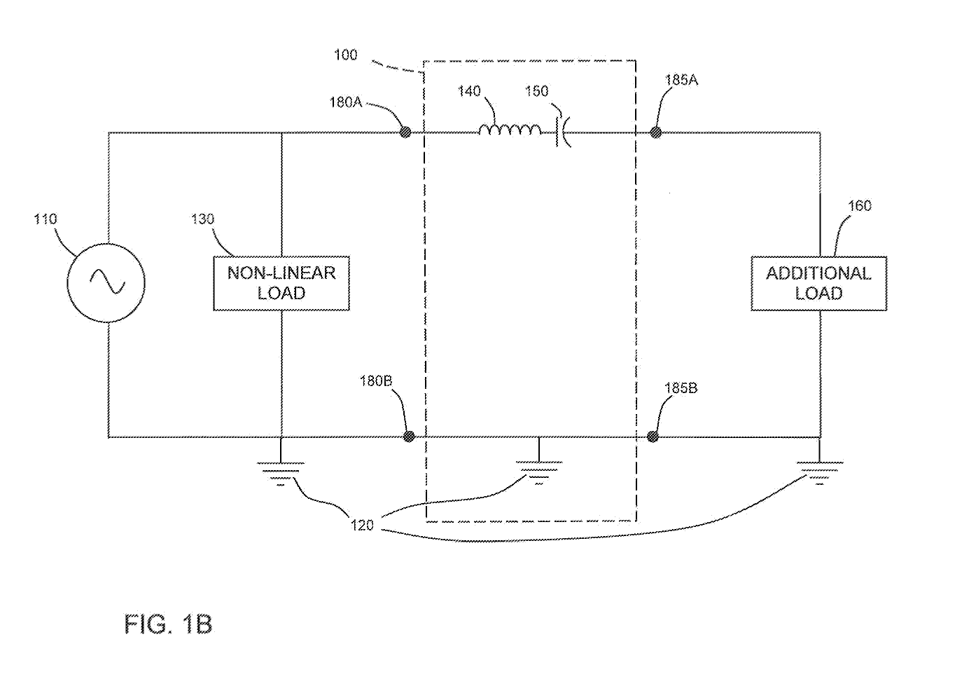

Turning now to the drawings, FIG. 1A illustrates an exemplary embodiment of the herein described systems and methods. Apparatus 100, indicated by the dashed box. Terminal 180A of apparatus 100 is coupled to a source of energy 110 that provides a periodic AC waveform having a fundamental frequency and a harmonic frequency component. Apparatus 100 is also coupled at terminal 185A to load 160. Apparatus 100 comprises a series resonant filter that includes inductor 140 having inductance (L) and capacitor 150 having capacitance (C), together forming a series L-C circuit. The values of L and C are selected so that the L-C circuit is tuned to the frequency of the harmonic component, forming a bandpass filter with a minimum impedance at the harmonic frequency. Apparatus 100 thus captures harmonic energy of the energy source and uses it to supply load 160, instead of shunting the harmonic energy to ground or otherwise wasting it, as is typical in the prior art. Thus, load 160 is not the earth, but instead is a useful electric load.

FIG. 1B is a simplified circuit diagram of an illustrative embodiment in which energy source 110 is an Alternating Current (AC) power supply that provides AC power to supply loads with power. In the illustrative embodiment, power supply 110 is a grounded single phase AC power supply, such as a nominal 120 Volt (V) common branch circuit, or mains, in a home or business for example, with one terminal or branch conductor of the power supply grounded to earth 120. Although a single phase grounded circuit is illustrated, those of ordinary skill in the art will appreciate that the system need not actually be grounded, and may comprise more than one phase. For example, an ungrounded neutral conductor may be substituted for ground. In addition, the herein described harmonic capturing apparatus need not be grounded at all. In that case, the apparatus may be coupled between the non-grounded or non-neutral conductors of the power supply and load, as will be described hereinafter. For another example, a three-phase, four wire grounded AC system may provide operating power to a load, such as a three-phase induction motor that drives a mechanical load. In that case, the herein described systems and methods may be applied to each of the branch phase conductors.

In FIG. 1B, power supply 110 provides power to non-linear load 130, resulting in harmonics arising on the supply line. In the prior art, such harmonics are commonly mitigated by providing a capacitive shunt to ground. In the illustrative embodiment, however, harmonic energy is captured by a series resonant L-C circuit comprising inductor 140, and capacitor 150. In FIG. 1, the inductor and capacitor are coupled in series and constitute a series resonant L-C circuit. The inductor and the capacitor are selected so that the L-C circuit is resonant at a desired harmonic of the fundamental frequency of the power supply 110. Accordingly, the series L-C circuit allows resonant current to pass through the L-C circuit, while effectively blocking the passage of currents at the fundamental and other resonant frequencies. The L-C circuit thus acts as a filter to draw off the harmonic current that exists on the fundamental circuit, or mains, and uses it to power a load 160 that is additional to and distinct from non-linear load 130. Illustratively, the power on the circuit from which the non-linear load 130 receives its power is supplied mainly at the fundamental frequency, and is referred to herein as the fundamental circuit. In contrast, the power on the circuit from which the additional load 160 receives its power is supplied mainly at the harmonic frequency that passes through the L-C circuit, and is referred to herein as the harmonic distribution circuit. The harmonic distribution circuit is coupled to the fundamental circuit via apparatus 100. The fundamental circuit is coupled to apparatus 100 at terminals 180A and 180B, while the harmonic distribution circuit is coupled to apparatus 100 at terminals 185A and 185B. As shown, the non-linear load 130, the apparatus 100, and the additional load 160 are each grounded. However, an exemplary embodiment will operate normally if another grounding configuration is used, such as only one ground that is shared by a neutral conductor coupled to the loads and apparatus 100, or even if the neutral conductor is not grounded. As shown, apparatus 100 is disposed between the non-linear load 130 and the additional load 160. However, apparatus 100 may alternatively be coupled between the power supply 110 and the non-linear load 130.

In an embodiment, only one apparatus input terminal 180A and one output terminal 185A may be provided. In that case, one terminal of the power supply 110 must be grounded or coupled to a neutral conductor, and one terminal of the additional load 160 must also be grounded or coupled to the neutral conductor, and apparatus 100 may be coupled at any point along the other, ungrounded terminal or supply line of the power supply (i.e., the non-neutral conductor that provides line voltage to the non-linear load 130).

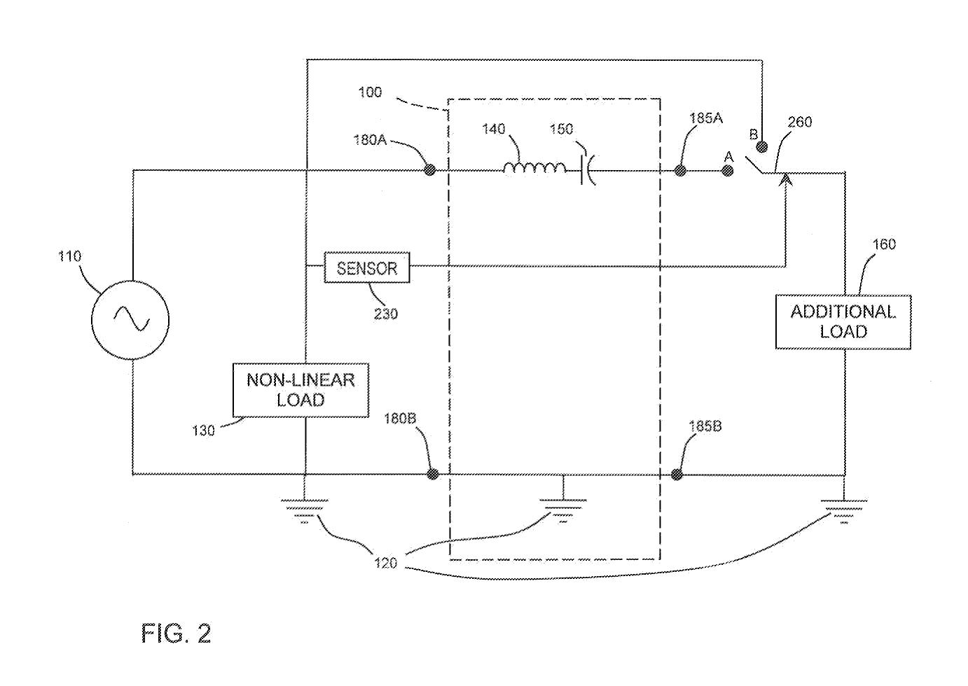

When the harmonics on the fundamental circuit arise due to the non-linear load 130, the harmonics will cease when the non-linear load is shut down or turned off, with the result that the additional load 160 would no longer be powered. In FIG. 2, a sensor 230 senses when the non-linear load is turned off, or more generally when insufficient harmonic energy is present on the fundamental circuit to power the additional load 160. In that case, sensor 230 causes switch 260 to switch the power supply for the additional load 160 from terminal A and the harmonic capturing apparatus 100 to terminal B and the fundamental circuit. Effectively, switch 260 switches the harmonic capturing apparatus out of the circuit that supplies additional load 160.

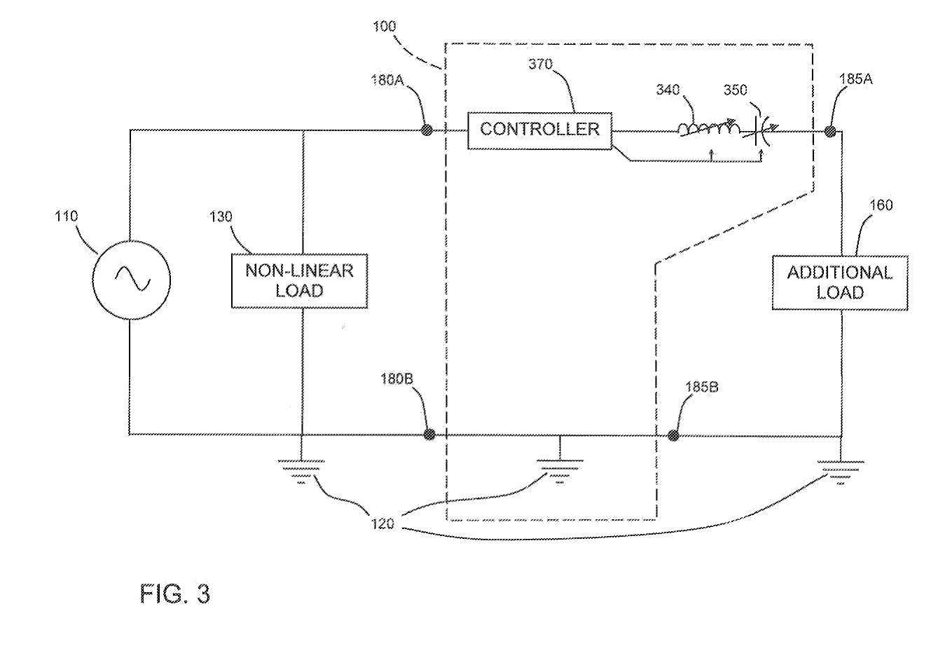

Illustratively, the inductor and capacitor may be static or may be variable. If one or both are variable, then the L-C circuit may be tuned to one harmonic frequency, then re-tuned to a different harmonic frequency. The tuning may be responsive to a harmonic energy monitoring device, for example, a harmonic meter that can determine which of a plurality of harmonics would provide the greatest amount of energy to load 160. FIG. 3 illustrates an exemplary embodiment comprising a variable inductor 340 and a variable capacitor 350, and a controller 370 comprising a harmonic meter, that can vary the inductance and capacitance of the inductor and/or capacitor, respectively. Any type of harmonic meter, variable inductor and/or variable capacitor may be used. Non-limiting examples of these elements include a harmonic meter that may perform a Fourier analysis on the current waveform on the fundamental circuit and select the harmonic frequency having the greatest amplitude. The variable inductor may comprise at least one terminal having a movable contact that can be moved along the surface of the inductor coil, increasing or decreasing the number of turns of the coil included in the circuit. And, the variable capacitor may comprise movable plates, for example, whereby the distance between the plates, or the amount of surface area of one plate or set of plates which overlaps another, can be adjusted. Alternatively, a plurality of series-coupled inductors and/or a plurality of parallel-coupled capacitors may be switched in and out of the L-C circuit to adjust the circuit's series resonant frequency to match a select harmonic.

Apparatus 100 may also comprise a plurality of series L-C branch circuits arranged in parallel, each branch tuned to a particular resonant frequency, whereby the energy of a plurality of harmonics may be captured. The branch circuits may be tuned to the same or different frequencies. Each series L-C branch circuit may be permanently included in the circuit, or may be switched in and out of the circuit, for example, responsive to a harmonic energy monitoring device. Further, any or all of the L-C branch circuits may comprise variable elements, so that the branch may be tuned to a preferred harmonic, as hereinbefore described.

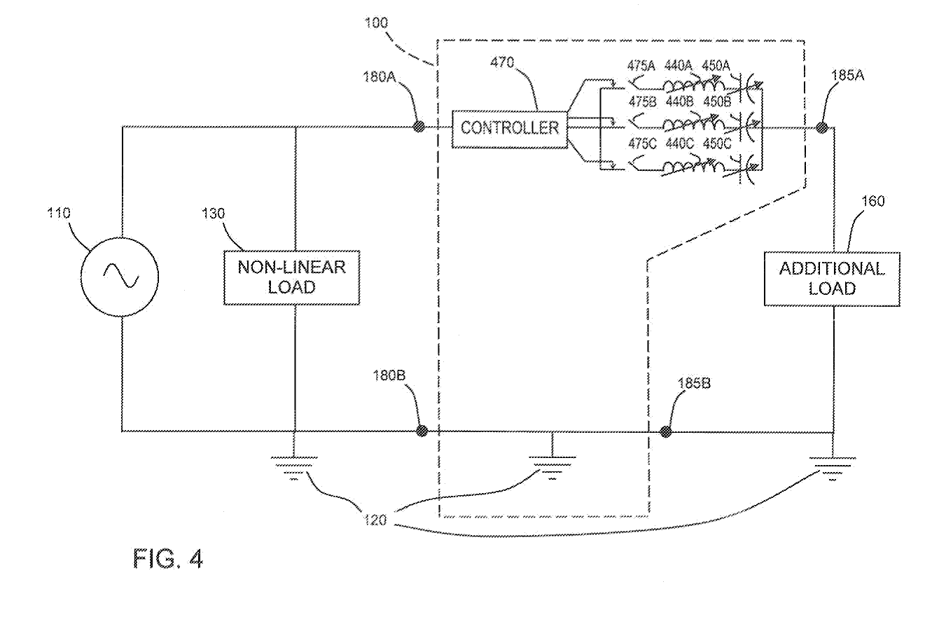

Turning now to FIG. 4, apparatus 100 illustratively comprises controller 170, which senses and analyzes the line current on the fundamental circuit, determines and selects the preferred harmonics, and can modify the inductance of variable inductors 440A, B, C and the capacitance of variable capacitors 450A, B, C to form L-C branch circuits tuned to the preferred harmonics. The preferred harmonics can be selected in accordance with any available parameter or combination of parameters of the fundamental circuit and/or one or more additional loads (160) coupled to the harmonic distribution circuit. Further, the branch circuits may be further configured by opening and/or closing switches 475A, B, C, which may be relays, for example. In FIG. 4, three branch L-C circuits are shown, each of which has a corresponding switch. However, any desired number of branch circuits may be used. Moreover, it is not necessary that every branch L-C circuit be controlled with a switch, and only select branches may be switched if desired. Further, two or more of the branches may be tuned to the same harmonic if desired.

In an exemplary embodiment, additional conditioning of the output of apparatus 100 may be performed, for example, to better match the characteristics of the captured harmonic energy to the characteristics of load 160. Such conditioning may be accomplished using techniques well known in the art.

In an exemplary implementation, apparatus 100 may be used to recover energy that is ordinarily wasted when coupling a direct current (DC) generator to the AC grid. It is known to convert the DC produced by certain renewable energy sources, such as solar panels or wind turbines, into alternating current as used on the electric distribution grid. The conversion process generally employs a grid-tie inverter (GTI), also known as a grid-interactive inverter or a synchronous inverter. However, the conversion process can generate a great deal of harmonic energy, which in the prior art is lost. Apparatus 100 may be used to recover at least some of the harmonic energy of the GTI output, and feed it back to the GTI input, thereby reducing the energy previously wasted in the conversion.

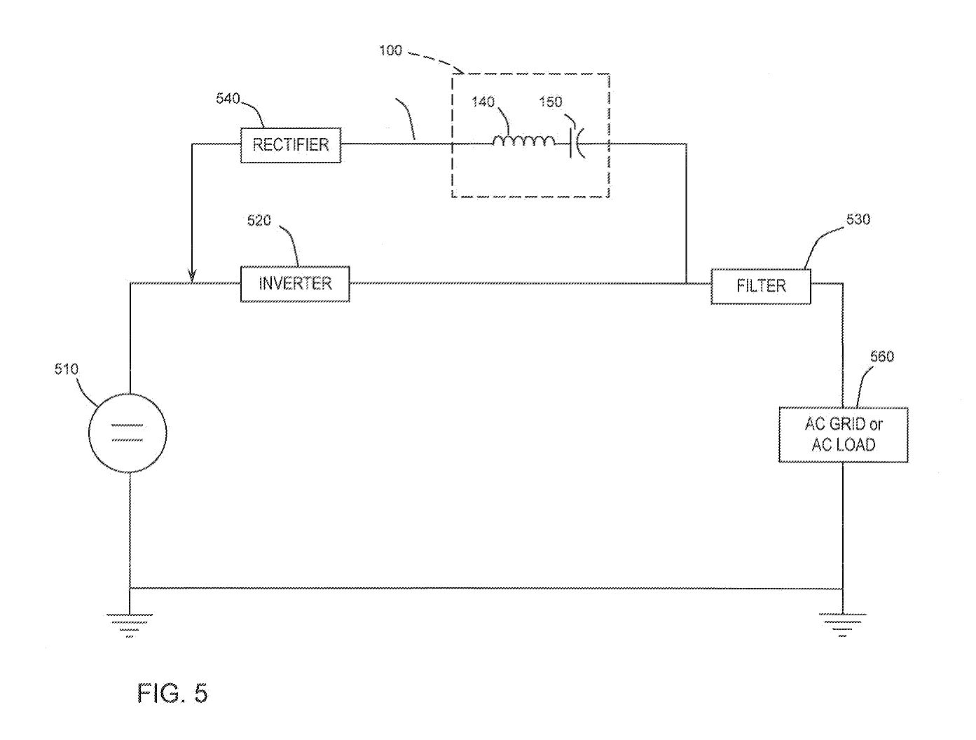

Referring now to FIG. 5, direct current (DC) generator 510, such as one or more wind turbines, solar panels, or the like, generates DC power to be coupled to the AC grid 560. The DC power generated must be converted to AC at the voltage and frequency of the grid. The conversion is generally accomplished using an inverter, 520. Depending on the type of inverter used, the inverter output may be a square wave, or another periodic wave more closely approximating the sine wave of the grid. The inverter output may be further modified by filter 530 to more closely approximate a sine wave, such as a Shaffner harmonics sine wave filter or the like. Apparatus 100 may be coupled to the inverter output to capture harmonic energy that in the prior art would be directed to ground or otherwise lost. The harmonic waveform at the output of apparatus 100 can be converted to a DC waveform, for example using rectifier 540, and directed to the input of the inverter, as shown. This arrangement provides increased energy in the output of inverter 520, and also presents a periodic waveform to the input of filter 530 with reduced harmonic content.

The arrangement illustrated in FIG. 5 can also represent implementations in which a DC power supply is used to supply an AC load 560. In some diesel-electric power trains, for example, a diesel engine powers a DC generator, whose output is used to power AC traction motors to drive the locomotive.

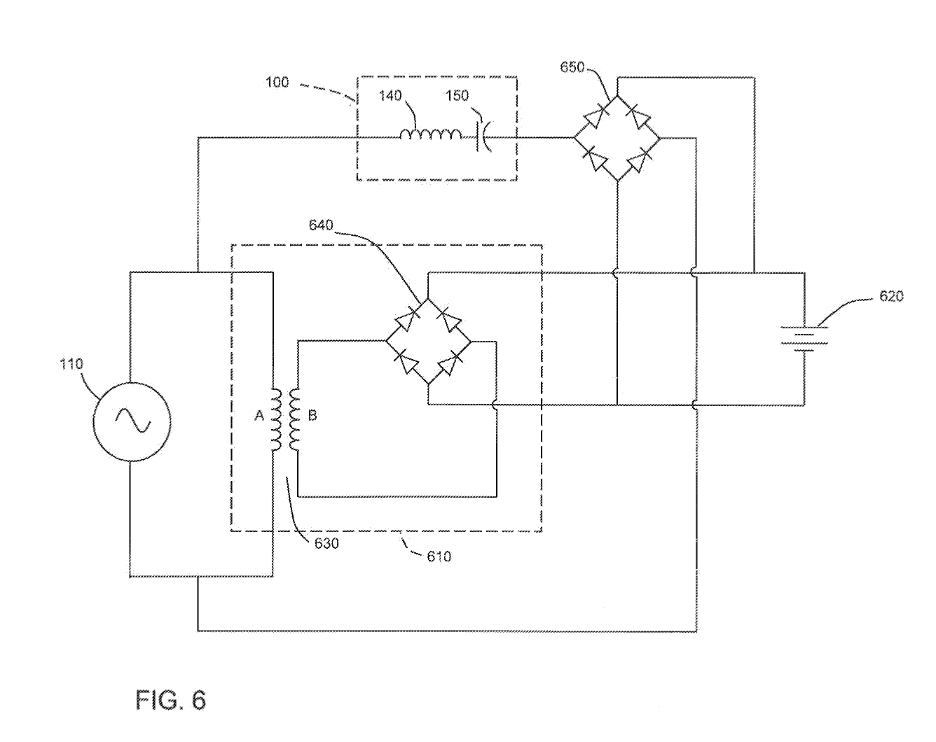

Turning now to FIG. 6, a battery charger indicated generally by dashed box 610 may be coupled to a battery 620 and to the fundamental circuit, causing harmonics to arise on the fundamental circuit. The battery charger comprises a step-down transformer 630 having a primary coil A and a secondary coil B, and a diode full-wave rectifier 640, although other kinds of rectifiers may also be used. Apparatus 100 is coupled to the fundamental circuit to capture the harmonics, and its output rectified by rectifier 650 and applied to the input of the battery being charged. Although apparatus 100 is shown coupled to the fundamental circuit at the primary side of the transformer, the apparatus may alternatively be coupled at the secondary side. Preferably, the voltage at the output of rectifier 650 is controlled to have a peak value approximately equal to the peak value of the output voltage of battery charger 630. For example, the peak voltages at the outputs of battery charger 630 and rectifier 650 can be sensed and compared, and the result used to control a variable autotransformer (not shown) coupled between rectifier 650 and battery 620 to keep the output of the battery charger from overwhelming the output of rectifier 650. By including apparatus 100, the energy received by the battery includes harmonic energy that it would not receive without apparatus 100, i.e., it receives more energy than it would without apparatus 100. Thereby, the time required to charge the battery is reduced. In addition, the harmonics existing on the fundamental circuit are mitigated.

Apparatus 100 may be implemented as follows. Perform a power quality survey using a power quality meter, such as a Fluke 435 meter or similar device. The survey should identify and quantify the harmonic components of the power supply waveform available on the fundamental circuit. The load survey should preferably be performed under full load conditions. To do so, determine the voltage and amperage of the fundamental circuit supplying a particular load or circuit under full load conditions. Couple the power quality meter to the fundamental (i.e., the supply) circuit. Select one or more harmonics that are preferred for use in supplying a harmonic distribution circuit that is distinct from the fundamental circuit and the load coupled thereto. Determine how much usable energy is available in those harmonics, the power that will be supply by each harmonic, and the current that will flow through each current-carrying component of apparatus 100, in accordance with practices well known in the art of circuit design. Tune one or more series resonant branches of apparatus 100 to resonate at the selected harmonics' frequencies, choosing the values of the inductor and capacitor components of each branch in accordance with practices well known in the art of series resonant circuits so that they resonate at the selected harmonic frequencies. Size the inductor and capacitor components in each branch in accordance with practices well known in the art of sizing electrical equipment so that they will withstand the current that was determined to flow through them under full load conditions. The components may be oversized somewhat, preferably by an amount in the range of 10% to 20%, to provide a margin of safety. Circuit protection may also be applied to the apparatus in accordance with practices well known in the art of circuit protection to protect the apparatus from harm due to lightening strikes, load equipment failure or malfunction, and the like.

Particular applications and benefits of the herein described apparatus, systems, and methods include the following.

The amount of energy wasted on a mains circuit due to lighting fixtures that use electronic drivers or ballasts can be reduced. Apparatus 100 can be coupled to the mains circuit and to a distinct harmonic distribution circuit, as shown in FIGS. 1 through 4 for example. A portion of a plurality of lighting fixtures can be supplied by the mains as non-linear loads 130, causing harmonics to arise on the mains. Apparatus 100 captures the harmonic energy on the mains and directs it to the harmonic distribution circuit, which is used to supply the remainder of the lighting fixtures as additional loads 160. Thereby, the efficiency of the lighting as a whole is effectively increased, and the harmonics on the mains are mitigated. Using such an arrangement, the efficiency of plasma, LED, and OLED displays, and lighting fixtures including induction, fluorescent, compact fluorescent, High-Intensity Discharge (HID), and other non-linear lighting can be improved.

The efficiency of converting DC to AC can be improved, as illustrated for example in FIG. 5. Thereby, the effective efficiency of solar, wind, and other DC power generation can be improved. A similar arrangement can be used in diesel-powered locomotives, regenerative braking energy capture, and the like.

The time to charge batteries can be reduced, as illustrated for example in FIG. 6. A similar arrangement can be used in charging electric vehicles, uninterruptible power supplies, rechargeable home appliances, and the like.

The output of apparatus 100 can be supplied to any type of resistive load coupled to the harmonic distribution circuit as loads 160 in FIGS. 1-4. For example, the captured harmonic energy can be used to power resistive lighting or heating elements directly, or to supplement power provided by a fundamental circuit to such loads. In addition, non-resistive loads that are able to utilize energy at the harmonic frequencies may be supplied using apparatus 100. Furthermore, the waveform of the harmonic energy available on the harmonic distribution circuit may be modified in accordance with practices well known in the art of power conditioning to adapt the energy on the harmonic distribution circuit for use with loads that cannot use the harmonic energy directly.

It should be appreciated that the herein described systems, methods, and apparatus may be modified, adapted, configured, and conducted as appropriate for any context at hand without departing from the spirit or scope of the claimed invention. Accordingly, it is intended that the appended claims cover such modifications and variations provided they come within the scope of the claims and their equivalents.

What is claimed is:

1. An apparatus for capturing power supply harmonics for use in powering a load, comprising a series resonant circuit with two terminals, a first terminal of which is coupled to an energy source having a periodic waveform comprising a sinusoidal fundamental frequency and a sinusoidal harmonic of the fundamental frequency, and a second terminal of which is coupled to a load that is not the earth, wherein the series resonant circuit is tuned to the harmonic frequency, whereby the energy of the harmonic is directed to the load.

2. The apparatus of claim 1, wherein the series resonant circuit comprises an inductor and a capacitor coupled in series.

3. The apparatus of claim 1, wherein the energy source is a non-grounded terminal of one phase of an alternating current (AC) power supply, and the load is a non-grounded terminal of a two-terminal load.

4. The apparatus of claim 3, wherein the AC power supply is a single phase power supply.

5. The apparatus of claim 3, wherein a terminal of the power supply that is not coupled to the series resonant circuit, and the terminal of the load that is not coupled to the series resonant circuit, are coupled together via a neutral conductor.

6. The apparatus of claim 5, wherein the neutral conductor is grounded.

7. The apparatus of claim 3, wherein a terminal of the power supply that is not coupled to the series resonant circuit is grounded, and the terminal of the load that is not coupled to the series resonant circuit is grounded.

8. The apparatus of claim 3, wherein the harmonic is the third harmonic, and the resonant circuit is tuned to the third harmonic of the fundamental frequency of the power supply.

9. The apparatus of claim 1, further comprising:
a sensor that senses when the energy of the harmonic is not sufficient to power the load; and
a switch coupled to the sensor that causes the load to be coupled to the power supply, bypassing the series resonant circuit in the event there is not sufficient harmonic energy to power the load.

10. The apparatus of claim 2, further comprising a controller that determines and selects a preferred energy source harmonic and causes the series resonant circuit to be tuned to the select harmonic frequency.

11. The apparatus of claim 1, further comprising:
at least one additional series resonant circuit arranged in parallel to the first series resonant circuit; and
a controller that determines and selects one or more preferred harmonics of the energy source and causes at least a portion of the series resonant circuits to be coupled to the energy source tuned to at least a portion of the preferred harmonics.

12. The apparatus of claim 1, wherein the energy source is the output of an inverter and the load is one of an Alternating Current (AC) grid and an AC load, further comprising:
a rectifier coupled to the output of the series resonant circuit and to the input of the inverter.

13. The apparatus of claim 12, wherein the AC circuit is an AC mains.

14. The apparatus of claim 1, wherein the energy source is an AC power supply providing power to a battery charger, further comprising:
a rectifier coupled to the output of the series resonant circuit and to the output of the battery charger.

15. The apparatus of claim 1, wherein the energy source is a three phase AC power supply, and the load is a three phase load, wherein the series resonant circuit is coupled between a first phase of the power supply and a first phase of the load, further comprising:
a second series resonant circuit coupled between a second phase of the power supply and a second phase of the load; and
a third series resonant circuit coupled between a third phase of the power supply and a third phase of the load.

16. The apparatus of claim 1, further comprising:
a non-linear load that has a characteristic fundamental frequency coupled to the input of the series resonant circuit.

17. An apparatus for capturing power supply harmonics for use in powering a load, comprising:
a series resonant circuit with two terminals, a first terminal of which is coupled to a first load which, when powered by a mains circuit, causes a periodic waveform to arise on the mains circuit having a sinusoidal fundamental frequency and a sinusoidal harmonic of the fundamental frequency, and a second terminal of which is coupled to a circuit that is not the mains circuit and arranged to supply energy to a load that is not the earth, wherein the series resonant circuit is tuned to the harmonic frequency, whereby the energy of the harmonic is directed to the load.
